(19) United States
(12) Patent Application Publication
(10) Pub. No.: US 2015/0123680 A1
(43) Pub. Date: May 7, 2015

(54) Inductive sensor and method of manufacturing an inductive sensor

(71) Applicant: Rolls-Royce Deutschland Ltd & Co KG, Blankenfelde-Mahlow (DE)

(72) Inventor: Knut ROSENAU, Herzfelde (DE)

(21) Appl. No.: 14/530,116

(22) Filed: Oct. 31, 2014

(30) Foreign Application Priority Data
Nov. 1, 2013 (DE) 10 2013 222 276.9

(51) Int. Cl. G01R 27/26; G01R 3/00; G01R 1/44

(52) U.S. Cl. CPC G01R 27/2611; G01R 1/44; G01R 3/00
USPC 324/654; 29/605

(57) ABSTRACT

An inductive sensor and to a method for manufacturing an inductive sensor is provided. The inductive sensor comprises a winding body, an induction coil made of a high-temperature resistant metal alloy and wound onto the winding body, and a metal casing at least partially surrounding the induction coil. Here, the induction coil is compressed with metal oxide powder inside the metal casing.

### CROSS-REFERENCE TO RELATED APPLICATION

This application claims priority to German Patent Application DE102013222276.9 filed Nov. 1, 2013, the entirety of which is incorporated by reference herein.

### BACKGROUND

This invention relates to an inductive sensor and a method for manufacturing an inductive sensor. A typical field of application for the invention is to provide a speed sensor for a gas turbine.

Inductive sensors are generally known. They include a coil wound onto a winding body and which is for example part of an oscillating circuit whose amplitude and/or frequency change in the electromagnetic field of a body passing by it. The result is measurement without wear and without contact.

There is generally a need to provide inductive sensors that are high-temperature resistant and accordingly usable in high-temperature environments, for example in the turbine area of a gas turbine. It is worthwhile here to provide high-temperature resistant inductive sensors that can manage without separate cooling.

### SUMMARY

An object underlying the present invention is accordingly to provide an inductive sensor which is high-temperature resistant even without a cooling provided. Another object is to provide a method for manufacturing such a high-temperature resistant inductive sensor.

It is a particular object of the present invention to provide solution to the above problems by an inductive sensor having the features as described herein and a method for manufacturing an inductive sensor having the features as described herein.

The solution in accordance with the invention provides for an induction coil wound onto a winding body and made of a high-temperature resistant metal alloy, e.g. a nickel-base alloy or stainless steel. The induction coil is at least partially surrounded by a metal casing. Inside the metal casing, the induction coil is compressed with metal oxide powder.

Compression of the induction coil inside the metal casing with metal oxide powder results in electrical insulation of the induction coil. In particular, the individual turns of the induction coil winding are insulated from one another by the metal oxide powder, thus avoiding the risk of a short-circuit. It must be borne in mind here that due to the required high-temperature resistance the induction coil is not provided with an insulating varnish or the like. A high-temperature resistant inductive sensor is provided which can be used for example to measure speed on rotors in hot-gas areas. Cooling of the sensor is not necessary, due to the heat-resistant materials used and to electrical insulation with metal oxide powder.

The feature in accordance with the invention that the induction coil is compressed with metal oxide powder inside the metal casing means that the metal oxide powder present in the metal casing is under a pressure that is higher than the ambient pressure. This is achieved in that the metal casing is deformed after insertion of the metal oxide powder into the metal casing, as will be explained below in detail with regard to the method in accordance with the invention. Deforming of the metal casing is accompanied by a compaction of the metal powder inside the metal casing, with the metal powder still being in powder form after compression and not sintered. The temperatures during compression and also during operation of the sensor, which are typically in the range between 400° C. and 800° C., in particular in the range between 600° C. and 800° C., are thus too low to cause sintering of the metal powder.

It can be provided here that an increased air pressure in the metal casing, also generally accompanying the deforming of the metal casing, is relieved by openings in the metal casing. To avoid an increased air pressure of this type, it can also be provided that deforming of the metal casing and hence compression of the induction coil inside the metal casing with metal oxide powder takes place in a vacuum.

The induction coil (i.e. the coil wire or the induction winding forming the induction coil) is made, as already stated, of a nickel-base alloy, of a stainless steel or of another high-temperature resistant metal alloy. In conformity with the usual definition in this respect, a steel with a proportion of more than 10.5% chromium dissolved in the austenitic or ferritic solid solution is referred to as stainless steel. The fact that the induction coil is made of a high-temperature resistant metal alloy means for example that the metal alloy is temperature-resistant up to a temperature of at least 400° C., at least 600° C. or at least 800° C., while at high temperatures too its electrical conductivity is good.

In an embodiment of the invention, the winding body is designed as a permanent magnet, i.e. it consists of a permanently magnetic material. This is provided in one embodiment with a ceramic coating to ensure insulation from the windings of the induction coil. The permanently magnetic material is also high-temperature resistant and can for example be cobalt-based or iron-based.

In an alternative embodiment, the winding body is designed as a ceramic winding body. It can be provided here that a permanent magnet is placed into the ceramic body to increase the inductance of the sensor. A permanent magnet of this type is also high-temperature resistant and can for example be cobalt-based or iron-based.

The metal casing is designed temperature-resistant in accordance with an embodiment of the present invention up to a temperature of at least 600° C., in particular up to a temperature of at least 800° C., so that it can perform its enclosing and protecting function even at these high temperatures. Depending on the high-temperature resistance needed of the inductive sensor, another temperature resistance of the metal casing can also be provided.

The metal casing is made for example of a nickel-base alloy, of stainless steel, of a titanium alloy or of another high-temperature resistant metal alloy.

According to a further embodiment of the invention, the metal casing is designed tubular. It can be provided here that the winding body forms a bottom area and a cover area in integrated form, to which the metal casing is fastened. To do so, it can for example be provided that the bottom area and the cover area each form a chamfer covered by a flanged rim of the metal tube, in order to positively fasten the metal tube to the bottom area and cover area of the winding body.

In other embodiments of the invention, the metal casing is designed closed, i.e. it forms for example a closed cylinder or a closed cube or another basic geometric shape, however with openings being provided for the passing through of cables and electrical connections. In this case, the bottom and cover of the casing are not formed by the winding body itself, but by the metal casing, with the winding body being arranged completely inside the metal casing. The cover and bottom can be formed out of the metal casing or be welded or brazed as separate components in the metal casing.

In all embodiments, the induction coil is compressed with metal oxide powder in the metal casing. To do so, for example compressive forces radially from the outside are applied to the sensor casing. This will be explained further and in more detail with regard to the method in accordance with the invention.

It can be provided that at least one groove is designed in the outside of the metal casing in which a sealing means is arranged, for example a high-temperature resistant sealing cord. This ensures outward sealing of the sensor from adjacent components, in particular against air leakage in the case of pressure differences.

A further embodiment of the invention provides that the winding body has an external thread intended and designed to receive the induction coil to be wound onto it.

The metal oxide powder with which the induction coil is compressed inside the metal casing is for example a magnesium oxide powder. However, other metal oxide powders can also be used, for example zirconium oxide or titanium oxide.

The invention furthermore relates to a method for manufacturing an inductive sensor. The method involves the following steps:
winding of an induction coil made of a high-temperature resistant metal alloy onto a winding body,
arrangement of the induction coil wound onto the winding body inside a metal casing together with a metal oxide powder,
sealing of the metal casing such that substantially no metal oxide powder can escape to the outside, and
then deforming of the metal casing, with the induction coil being compressed with the metal oxide powder and the metal casing receiving its finalized outer shape. The metal power is here still present in powder form after compression and not sintered.

The metal casing is, with the method in accordance with the invention, therefore deformed after insertion of the induction coil wound onto the winding body and its embedding in metal oxide powder. The induction coil is compressed with the metal oxide powder by this deforming operation. The air contained in the metal oxide powder can if necessary escape through suitable openings in the metal casing, bottom and/or cover or through the passage openings of the sensor windings.

The sealing of the metal casing such that substantially no metal oxide powder can escape to the outside means that the proportion of metal oxide powder that might escape is less than 10% of the total mass of the metal oxide powder. Sealing of the metal casing can be provisional or final. If sealing is only provisional, final sealing follows the completion of the deforming operation.

The metal casing is deformed in one embodiment of the invention by compressive forces being applied radially from the outside to the metal casing, so that the metal casing is pressed in the radial direction. Depending on the shape of the metal casing, this can lead to the sensor casing resembling a compressed crimp sleeve after the pressing operation. Pressing from the outside in the radial direction is in one embodiment performed several times at offset circumferential angles in order to obtain an increased roundness of the pressed metal casing.

Compressive forces are applied in the radial direction to the metal casing in such a way that a cover area of the metal casing, through which cables or other electrical connections pass, is not deformed during pressing, so that the electrical connections are not damaged. To do so, it can be provided that the metal casing is deformed exclusively in the radial direction in an axial area of the metal casing situated between the cover area and the bottom area of the metal casing.

Generally speaking, however, embodiments are also conceivable in which the pressing operation has an axial component or is in the axial direction. For example it is conceivable that the bottom area of the metal casing, where this is not passed through by cables or other electrical connections, is pressed at least partially in the axial direction. In the case of compressive forces being applied in the axial direction, they must however be applied in such a way that the areas of the sensor used for passing through electric cables and other electrical connections are not damaged. Care must be taken here that the windings do not slip axially and that no short-circuiting occurs due to a mutual contact.

According to an embodiment of the method in accordance with the invention, the metal casing has an outward bulge prior to deforming of the metal casing. The metal casing is deformed in that a pressure is exerted from the outside onto the bulge and the latter is at least partially eliminated by this. For example, it can be provided that the metal casing is designed as a metal tube, said metal tube having a bulge before deforming which is substantially eliminated by deforming (e.g. by application of compressive forces in the radial direction from the outside).

However, deforming of the metal casing can also be achieved in a different way to application of a compressive force onto a bulge of the metal casing: for example, it can alternatively be provided that the metal casing has folds like the bellows of a concertina, where by application of a compressive force deforming is achieved by the concertina-like folds reducing their distance to one another, so that the metal oxide powder inside the metal casing is compressed.

All deforming and pressing operations can be assisted by the application of high-frequency oscillations, transmitted by parts of the pressing device via the metal casing, cover and/or bottom into the metal oxide powder to be compacted. The high-frequency oscillations can in particular be applied in the frequency range from 20 kHz to 100 kHz, to assist a more even compaction of the metal oxide powder and hence achieve a more even electrical insulation effect of the metal oxide powder.

In particular, the application of high-frequency oscillations during the pressing operation permits a more even compaction of the metal oxide powder during performance of axial compressive movements.

### BRIEF DESCRIPTION OF THE DRAWINGS

The present invention is described in the following with reference to the figures of the accompanying drawing, showing several exemplary embodiments.

FIG. 1 shows an exemplary application of the present invention, with an inductive sensor being used as speed sensor in the hot area of a gas turbine.

FIG. 2 shows an enlarged axial partial sectional view of an exemplary embodiment of an inductive sensor in accordance with the present invention, with the inductive sensor being arranged in a pressing device which is schematically illustrated.

FIG. 3A shows a first alternative exemplary embodiment of the winding body of the inductive sensor of FIG. 2.

FIG. 3B shows a second alternative exemplary embodiment of the winding body of the inductive sensor of FIG. 2.

FIG. 3C shows a third alternative exemplary embodiment of the winding body of the inductive sensor of FIG. 2.

FIG. 4A shows a third alternative exemplary embodiment of a winding body of an inductive sensor, with the winding body integrating a bottom area and a cover area of the sensor and being provided with a ceramic coating.

FIG. 4B shows a fourth alternative exemplary embodiment of a winding body of an inductive sensor, with the winding body integrating a bottom area and a cover area.

FIG. 4C shows a fifth alternative exemplary embodiment of a winding body of an inductive sensor, with the winding body integrating a bottom area and a cover area.

FIG. 5A shows a sixth alternative exemplary embodiment of a winding body of an inductive sensor, with the winding body integrating a bottom area.

FIG. 5B shows a seventh alternative exemplary embodiment of a winding body of an inductive sensor, with the winding body integrating a bottom area.

FIG. 5C shows an eighth alternative exemplary embodiment of a winding body of an inductive sensor, with the winding body integrating a bottom area.

FIG. 6A shows the arrangement of an induction coil wound onto a winding body in a tubular metal casing, which features an outward bulge before the metal casing is deformed.

FIG. 6B shows the inductive sensor of FIG. 6A after deforming of the metal casing, with the outward bulge of the metal casing having been eliminated.

FIG. 6C shows an alternative exemplary embodiment of the inductive sensor of FIG. 6B, with grooves, each with a sealing cord inside, being provided on the outside of the metal casing.

FIG. 7A shows a further embodiment of a winding body arranged in a metal tube with an outward bulge before deforming of the metal tube, with the winding body featuring an integrated cover and an integrated bottom.

FIG. 7B shows the inductive sensor of FIG. 7A after deforming of the metal casing, with the outward bulge of the metal casing having been eliminated.

FIG. 7C shows an alternative exemplary embodiment of the inductive sensor of FIG. 7B, with grooves, each with a sealing cord inside, being provided on the outside of the metal casing.

### DETAILED DESCRIPTION

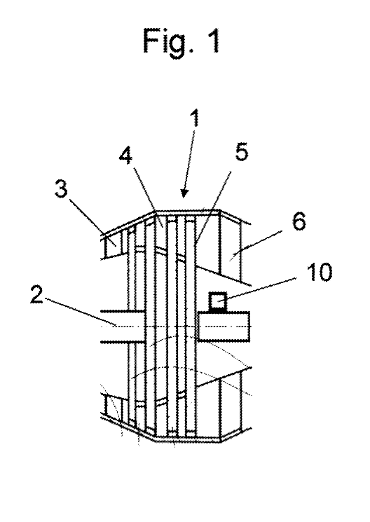

FIG. 1 shows an exemplary application for the use of a high-temperature resistant inductive sensor 10 in accordance with the invention. The inductive sensor 10 is arranged in the area of a gas turbine 1, designed in a manner known per se and including in the flow direction, one behind the other, an air inlet 3, a turbine 4 with at least one turbine rotor 5, and an exhaust nozzle 6, all of which being arranged about a center engine axis 2.

The inductive sensor 10 is in the exemplary embodiment of FIG. 1 arranged close to the center engine axis 2. Generally speaking, it can also be arranged in other areas of the gas turbine 1. The inductive sensor 1 is for example used for speed measurement on a turbine rotor 5.

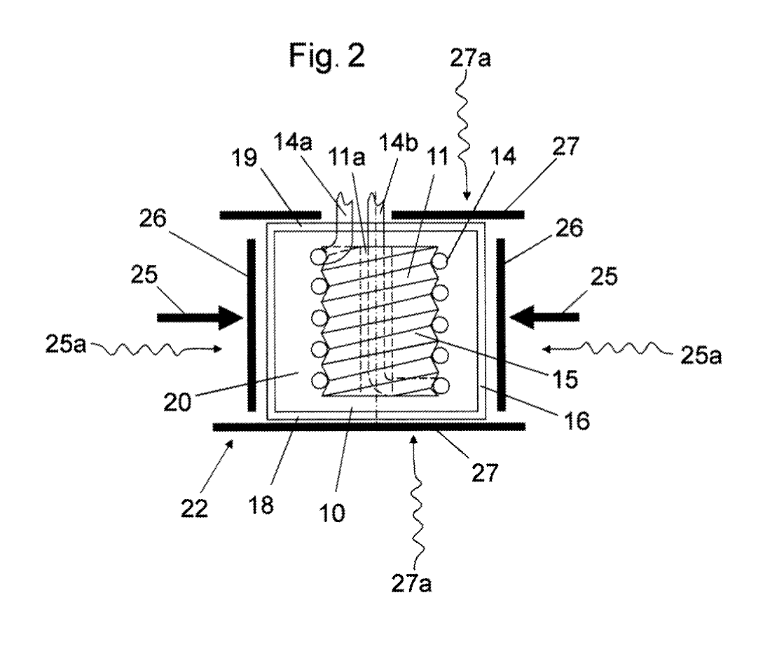

FIG. 2 shows a first exemplary embodiment of a high-temperature resistant inductive sensor 10. The inductive sensor 10 includes a winding body 11 wound with an induction winding 14, with a coil 15 being provided. The induction winding 14 has two winding ends 14a, 14b, of which the one winding end 14b is routed inside a central axial recess 11a of the winding body 11 opening at the lower rim of said winding body 11 to its outer surface. The winding body 11 can have an external thread to facilitate arrangement of the induction winding 14 and to position the windings at a defined distance from one another.

The coil 15 is arranged inside a metal casing 16 and is compressed inside the metal casing 16 with a metal oxide powder 20 used for electrical insulation.

The metal casing 16 is designed temperature-resistant up to a required minimum temperature which is for example 600° C. or 800° C. It is made for example of a nickel-base alloy, of stainless steel, of a titanium alloy or of another high-temperature resistant metal alloy. The winding body 11 is made, for example, of a ceramic or a permanently magnetic material. The induction winding 14 is made of a high-temperature resistant metal alloy, for example a nickel-base alloy or a stainless steel. The compressed metal oxide powder 20 is for example a magnesium oxide, zirconium oxide or titanium oxide powder.

The inductive sensor of FIG. 2 furthermore has a bottom 18 and a cover 19. In the exemplary embodiment shown, however not necessarily, the bottom 18 and the cover 19 form part of the casing, and can therefore also be made of metal. Alternatively, the bottom 18 and cover 19 can be ceramic. The winding ends 14a, 14b of the induction winding 14 project upwards out of the cover 19 through openings not shown in detail.

An axial direction and a radial direction are defined by the shape of the winding body 11 and by the winding of the induction coil 15.

To compress the metal oxide powder 20 inside the metal casing 16, compressive forces 25 are applied to the metal casing 16 from the outside in the radial direction. This is done for example using movable jaws 26 of a pressing device 22 which are movable and press against the metal casing 16 in the radial direction in order to apply the compressive forces 25 and hence deform the metal casing 16. It can be provided here that radial pressing is done several times at offset angles to obtain an increased roundness of the metal casing 16. The movable jaws 26 are ideally designed half-round to follow the contour of the metal casing.

The axial extent of the movable jaws 26 is such that there is no deformation of the metal casing 16 in the area of the bottom 18 and in the area of the cover 19. This reliably prevents in particular any damage otherwise possible to the connections or winding ends 14a, 14b, and also ensures a defined distance between the winding body 11 and the bottom 18. In the axial direction, the metal casing 16 is arranged in a rigid part of the pressing device 22, which is formed for example by rigidly clamped plates 27.

High-frequency oscillations 25a, 27a can be applied to the components of the pressing device 22, such as jaws 26, and/or plates 27, to assist the pressing operation and to achieve a more even and higher compaction of the metal oxide powder 20.

After the pressing operation, the hollow-cylindrical wall of the metal casing 16 is re-duced in its diameter, so that the metal casing 16 resembles a compressed crimp sleeve (with undeformed bottom 18 and cover 19). The metal oxide powder 20 in the metal casing 16 is compressed by the deforming operation, i.e. the metal oxide powder 20 in the metal casing 16 is under a pressure higher than the ambient pressure. The internal pressure of the metal oxide powder can usually be 10 to 50 bars, but can also have a different value.

The pressing operation leading to a deformation of the metal casing 16 can, generally speaking, be achieved in many ways. A radial pressing operation with two movable plates 26, as shown in FIG. 2, must be understood only as an example. For instance, the pressing operation can also be achieved by one or more rollers contacting the outside of the cylindrical metal casing 16 and exerting a compressive force. The pressing operation can also include axial components, as long as it is ensured that the winding ends 14a, 14b are not damaged, the windings 14 on the winding body 11 are not displaced and a defined distance from the winding body 11 to the bottom 18 is achieved.

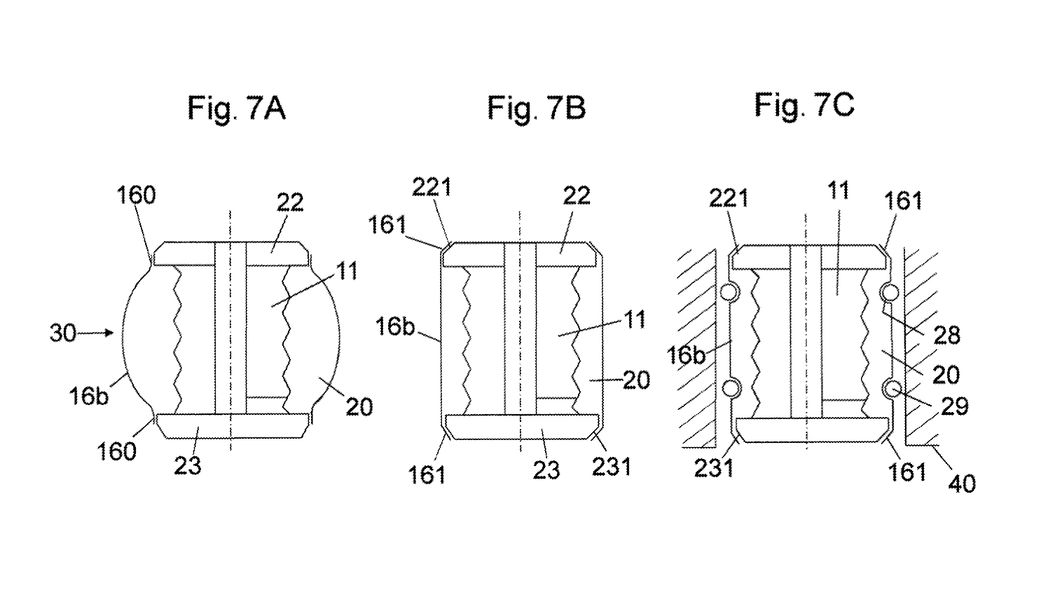

It is furthermore pointed out, as will be explained below with reference to the exemplary embodiments of FIGS. 7A-7C, that the bottom 18 and the cover 19 do not have to be an integral part of the metal casing 16, but alternatively can also be designed as separate parts or as integrated components of the winding body 11.

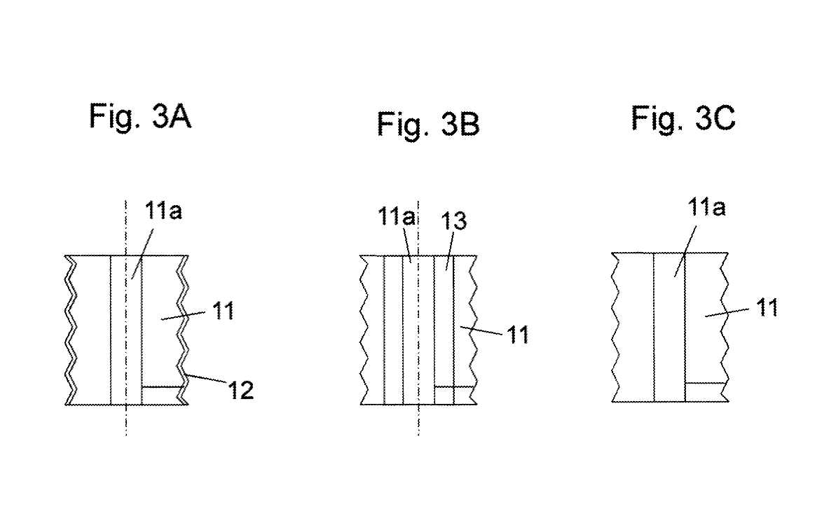

FIG. 3A shows an alternative exemplary embodiment of the winding body 11 of FIG. 2. In this exemplary embodiment the winding body 11 is made of a permanently magnetic material. For insulation from the windings 14 (not shown) of the induction coil 15, the permanently magnetic winding body 11 is provided with a ceramic coating 12.

FIG. 3B shows a further exemplary embodiment of a winding body 11. In this exemplary embodiment, the ceramic winding body 11 is designed hollow, forming a hollow-cylindrical receptacle 13. The latter is intended and designed to receive a permanent magnet (not shown), to increase the inductance of the sensor. A permanent magnet of this type is high-temperature resistant and can for example be cobalt-based or iron-based.

FIG. 3C shows a ceramic winding body without permanent magnet.

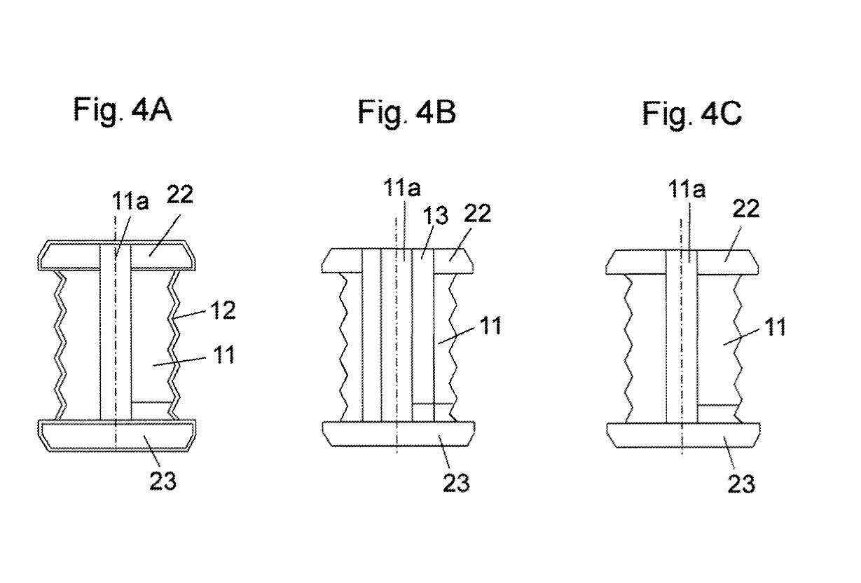

FIG. 4A shows a further exemplary embodiment of the winding body 11. A cover 22 and a bottom 23 of the inductive sensor are integrated into the winding body 11 and designed in one piece with the latter. In the exemplary embodiment of FIG. 4A, the winding body 11 is made of a permanently magnetic material, for which reason the winding body 11 furthermore has a ceramic coating 12.

The winding body 11 of FIG. 4B is made of a ceramic material. Here too, a cover 22 and a bottom 23 are integrated into the winding body 11. The winding body 11 has a recess 13 for receiving a permanent magnet.

FIG. 4C shows an exemplary embodiment of a ceramic winding body 11 with integrated cover 22 and bottom 23, which has no receptacle for a permanent magnet.

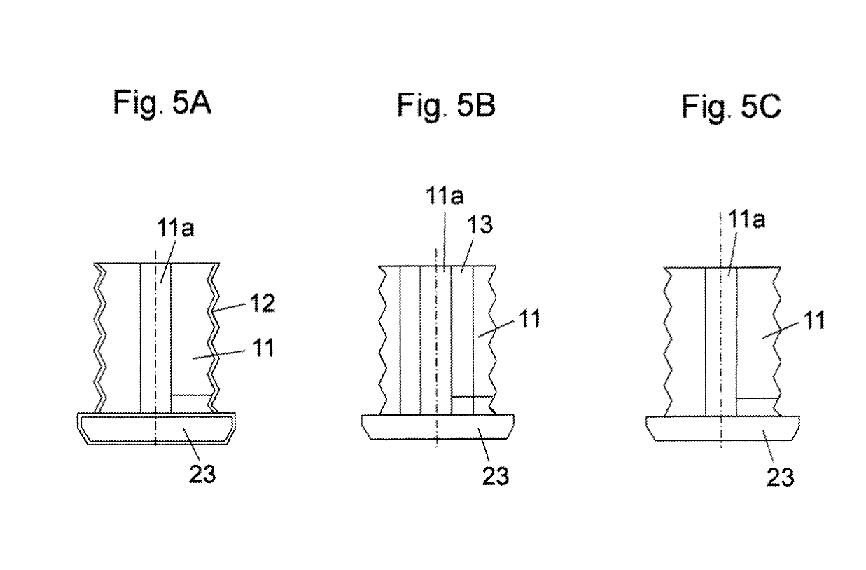

FIGS. 5A to 5C show winding bodies 11 according to FIGS. 4A to 4C, with the winding body 11 however only having an integrated bottom 23 (or alternatively an integrated cover 22).

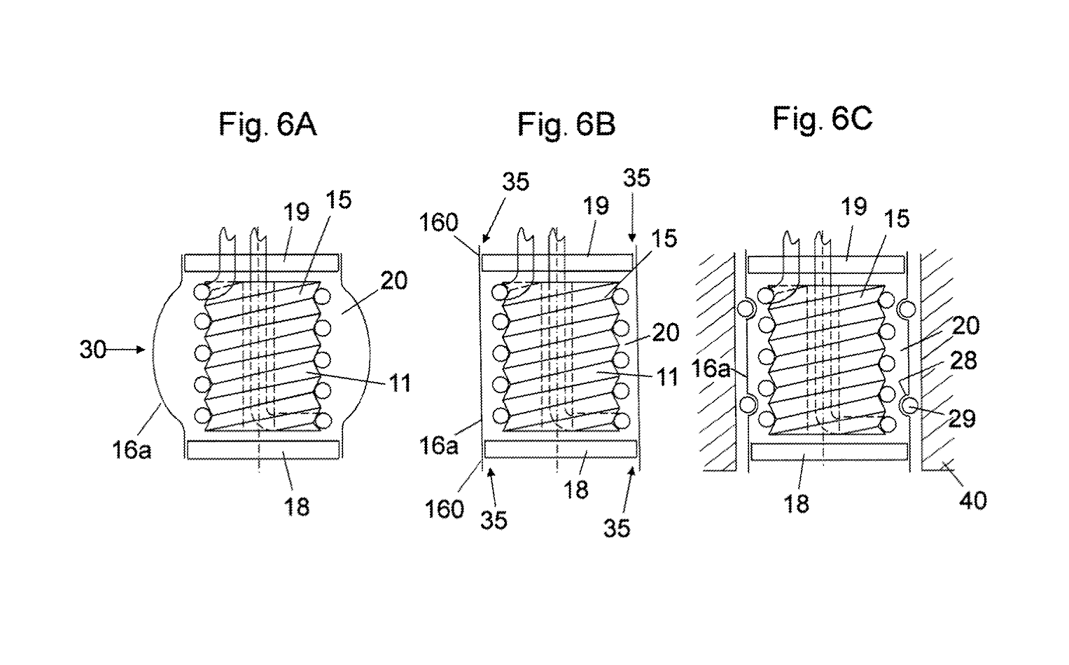

FIGS. 6A and 6B show an exemplary embodiment of an inductive sensor, with FIG. 6A showing the state before a deformation of a metal casing and FIG. 6B showing the state after deformation of the metal casing. According to FIG. 6A, an induction coil 15 wound onto a winding body 11 and which is for example designed according to the embodiment of FIG. 2, is arranged together with metal oxide powder 20 inside a metal casing formed by a metal bottom 18, a metal cover 19 and a metal tube 16a, said metal tube 16a having an outward bulge 30. The metal tube 16a movably contacts at its ends a bottom 18 and a cover 19, so that a substantially closed metal casing with metal oxide powder 20 arranged therein is obtained.

This is followed by a radial pressing of the metal tube 16a, for example using pressing jaws 26 corresponding to the movable jaws 26 of FIG. 2 or using rollers. It can be provided here that pressing jaws and the like are applied several times at offset angles in order to achieve roundness of the metal tube 16a. The bulge 30 is eliminated by the application of compressive forces axially from the outside to the metal tube 16a. This is accompanied by compression of the metal oxide powder 20 inside the metal casing 16a, 18, 19.

The elimination of the bulge 30 of the metal tube 16a by the application of compressive forces against said metal tube 16a is accompanied by an extension of the metal tube 16a, so that its front-side ends 160 now further project beyond the bottom 18 and the cover 19. A firm connection between the metal tube 16a and the bottom 18 and the cover 19 is now achieved using welded or brazed seams 35.

Alternatively to the welded or brazed seams, the bottom 18 and/or the cover 19 can be flange-mounted into the metal tube 16a, in particular when bottom 18 and cover 19 are made of a ceramic material.

FIG. 6B shows the inductive sensor after completion of the pressing operation. The metal tube 16a is now designed substantially cylindrical.

FIG. 6C shows a modification of the inductive sensor of FIG. 6B, where one or more circumferential grooves 28 are provided in the outside of the metal casing 16a, in each of which grooves a sealing means, for example a sealing cord 29, is arranged. This permits sealing of the inductive sensor from external components forming for example a sensor seat 40.

FIGS. 7A and 7B show a further exemplary embodiment of an inductive sensor before and after the deforming operation of the metal casing, with the induction coil not being shown. In the exemplary embodiment of FIGS. 7A and 7B, the cover 22 and the bottom 23 are integrated into the winding body 11 according to the embodiments of FIGS. 4A to 4C. In this exemplary embodiment, therefore, only a metal tube 16b is made of metal, while the bottom 23 and the cover 22 of the sensor are provided by the ceramic winding body 11.

In the embodiment of FIG. 7A too, the metal tube 16b has in the initial state an outward bulge 30. The ends 160 of the metal tube 16b are not firmly connected to the cover 22 or the bottom 23 before performance of the deforming operation, so that a relative movement is still possible. However they are in direct contact with the lateral edges of the cover 22 and the bottom 23, so that substantially no metal oxide powder 20 can escape during the pressing operation.

FIG. 7B shows the inductive sensor after performance of the pressing operation for deforming the metal casing 16b. The pressing operation itself is performed as described in relation to FIGS. 6A and 6B. Due to the pressing operation the axial extent of the metal tube 16b has increased. This is used to provide a flange 161 at the ends of the metal tube 16b after the end of the deforming operation, with the flange contacting chamfered edges 221, 231 of the cover 22 and the bottom 23, thus providing a positive seal of the casing, which in this exemplary embodiment consists of the metal casing 16b and the bottom 23 and cover 22 integrated into the ceramic winding body.

In the exemplary embodiment of FIG. 7B too, it can be provided, similarly to the exemplary embodiment of FIG. 6C, that on the outside of the metal casing 16b one or more circumferential grooves 28 are formed, in each of which a sealing means, for example in the form of a sealing cord 29, is arranged to ensure sealing from an adjacent structure such as a sensor seat 40 for example. This is shown in FIG. 7C.

In further embodiments of the invention, winding bodies 11 are placed into a metal casing only with integrated bottom 23 according to FIGS. 5A-5C or only with integrated cover 22. The arrangement and the compression correspond to FIGS. 7A-7B, where however either only the bottom 23 or only the cover 22 is integrated into the ceramic winding body 11. The part not integrated here (cover or bottom) is provided in accordance with FIGS. 6A-6B.

The present invention, in its design, is not limited to the above exemplary embodiments which are only to be understood as examples. For instance, the shape and design of the winding body and of the metal casing can differ from the exemplary embodiments shown. Also, the metal casing can be deformed in a different way to that described. It is furthermore pointed out that the features of the individual exemplary embodiments described of the invention can be combined with one another in various combinations. Where areas are defined, they include all values within these areas and all part-areas within an area.

1. An inductive, comprising
a winding body,
an induction coil made of a high-temperature resistant metal alloy and wound onto the winding body, and
a metal casing at least partially surrounding the induction coil,
with the induction coil being compressed with metal oxide powder inside the metal casing.

2. The sensor in accordance with claim 1, wherein the winding body is designed as a high-temperature resistant permanent magnet and provided with a ceramic coating.

3. The sensor in accordance with claim 1, wherein the winding body is designed as a ceramic winding body.

4. The sensor in accordance with claim 3, wherein a high-temperature resistant permanent magnet, in particular made of a cobalt- or iron-based metal alloy, is placed into the ceramic winding body.

5. The sensor in accordance with claim 1, wherein the metal casing is designed temperature-resistant up to a temperature of at least 600° C., in particular up to a temperature of at least 800° C.

6. The sensor in accordance with claim 1, wherein the metal casing is made of a nickel-base alloy, of stainless steel, of a titanium alloy or of another high-temperature resistant metal alloy.

7. The sensor in accordance with claim 1, wherein the metal casing is designed tubular or bellow-shaped.

8. The sensor in accordance with claim 1, wherein the winding body forms a cover area and a bottom area, to which the metal casing is fastened.

9. The sensor in accordance with claim 6, wherein the metal casing is designed tubular or bellow-shaped and the cover area and the bottom area each form a chamfer positively contacted by a flanged rim of the formed metal casing.

10. The sensor in accordance with claim 1, wherein in the outside of the metal casing, at least one circumferential groove is provided, in which a sealing means, for example a high-temperature resistant sealing cord, is arranged.

11. The sensor in accordance with claim 1, wherein the induction coil is made of a nickel-base alloy or of stainless steel.

12. The sensor in accordance with claim 1, wherein the sensor is appropriate for being used as speed sensor.

13. A method for manufacturing an inductive sensor, involving the following steps:
winding of an induction coil made of a high-temperature resistant metal alloy onto a winding body,
arrangement of the induction coil wound onto the winding body inside a metal casing together with a metal oxide powder,
sealing of the metal casing such that substantially no metal oxide powder can escape to the outside, and
then deforming of the metal casing, with the induction coil being compressed with the metal oxide powder and with the metal power still being present in powder form after compression and not sintered.

14. The method in accordance with claim 13, wherein the metal casing for deforming is pressed at least once in the radial direction from the outside.

15. The method in accordance with claim 13, wherein the metal casing has an outward bulge prior to deforming and that the metal casing is deformed in that a pressure is exerted from the outside onto the bulge.

16. The method in accordance with claim 14, wherein the metal casing is designed as a metal bellow, said metal bellow having a bulge before deforming which is substantially eliminated by deforming.

17. The method in accordance with claim 13, wherein in order to assist compaction of the metal oxide powder high-frequency oscillations are transmitted into the metal oxide powder.

18. The method in accordance with claim 13, wherein at least compression of the induction coil with metal oxide powder takes place in a vacuum.
